(19) United States
(12) Patent Application Publication
(10) Pub. No.: US 2024/0429247 A1
(43) Pub. Date: Dec. 26, 2024

(54) ARRAY SUBSTRATE AND METHOD FOR MANUFACTURING ARRAY SUBSTRATE

(71) Applicant: Chengdu Vistar Optoelectronics Co., Ltd., Chengdu (CN)

(72) Inventors: Zhen ZHANG, Chengdu (CN); Xiuqi HUANG, Chengdu (CN); Xuan CAO, Chengdu (CN); Zongyi XIONG, Chengdu (CN); Fei HUANG, Chengdu (CN); Yunlei CHEN, Chengdu (CN); Aimin XING, Chengdu (CN); Liang DENG, Chengdu (CN); Zhibo YAO, Chengdu (CN)

(73) Assignee: Chengdu Vistar Optoelectronics Co., Ltd., Chengdu (CN)

(21) Appl. No.: 18/751,892

(22) Filed: Jun. 24, 2024

(30) Foreign Application Priority Data
Jun. 25, 2023 (CN) 202310757462.7

(51) Int. Cl. H01L 27/12

(52) U.S. Cl. CPC H01L 27/1244; H01L 27/1259

(57) ABSTRACT

An array substrate and a method for manufacturing an array substrate. The array substrate includes a display region and a non-display region. The non-display region is located at least on one side of the display region. The array substrate also includes a substrate, a driver circuit layer, and a pad layer. The substrate includes a first surface and a second surface that are disposed opposite to each other and a side surface connected to the first surface and the second surface. The driver circuit layer is disposed on the first surface and includes at least one signal layer. The at least one signal layer extends from the display region to the non-display region. The pad layer is disposed in the display region and includes at least one pad. The at least one pad is electrically connected to the at least one signal layer.

### CROSS-REFERENCE TO RELATED APPLICATION(S)

This application claims priority to Chinese Patent Application No. 202310757462.7 filed Jun. 25, 2023, the disclosure of which is incorporated herein by reference in its entirety.

### TECHNICAL FIELD

Embodiments of the present application relate to the technical field of display, in particular, an array substrate and a method for manufacturing an array substrate.

### BACKGROUND

The micro light-emitting diode/mini light-emitting diode (micro-LED/mini-LED) display technology has become one of the hot spots in the development of future display technology due to characteristics such as independent control of pictures, independent control of lighting, high brightness, low power consumption, ultra-high resolution, and high colorfulness.

The current Micro-LED/Mini-LED display panels can be equipped with circuits on the

back and use side wires to connect the circuits on the back and the circuits on the front to reduce the size of the frame of the Micro-LED/Mini-LED display panels.

### SUMMARY

The present application provides an array substrate and a method for manufacturing an array substrate.

In a first aspect, one or more embodiments of the present application provides an array substrate. The array substrate includes a display region and a non-display region. The non-display region is at least located on one side of the display region. The array substrate also includes a substrate, a driver circuit layer, and a pad layer.

The substrate includes a first surface and a second surface that are disposed opposite to each other, and a side surface connected to the first surface and the second surface.

The driver circuit layer is disposed on the first surface and includes at least one signal layer. The at least one signal layer extends from the display region to the non-display region.

The pad layer is disposed in the display region and includes at least one pad. The at least one pad is electrically connected to the at least one signal layer.

In some embodiments, the array substrate also includes a side wire and a line layer disposed on the second surface.

The side wire is disposed on a side of the substrate. One end of the side wire is connected to the at least one signal layer, and another end of the side wire is connected to the line layer.

In some embodiments, the at least one signal layer in the non-display region extends to an edge of the first surface, and one end of the side wire is lapped on the surface of the at least one signal layer; or a certain distance is reserved between the at least one signal layer in the non-display region and an edge of the first surface, and one end of the side wire extends along the first surface to be lapped on the surface of the at least one signal layer.

In some embodiments, the at least one signal layer includes a first signal layer and a second signal layer; in the non-display region, the first signal layer covers the second signal layer; and one end of the side wire at least covers part of the surface of the first signal layer; or in the non-display region, the first signal layer at most covers part of the second signal layer; and one end of the side wire covers at least one of the following: part of the surface of the first signal layer and part of the surface of the second signal layer.

In some embodiments, the driver circuit layer also includes a first insulating layer, and the first insulating layer is disposed in the display region and disposed between the first signal layer and the second signal layer.

In some embodiments, the line layer in the non-display region extends to an edge of the second surface, and another end of the side wire is lapped on the surface of the line layer; or a certain distance is reserved between the line layer in the non-display region and an edge of the second surface, and another end of the side wire extends along the second surface to be lapped on the surface of the line layer.

In some embodiments, the line layer at least includes a first sub-line layer and a second sub-line layer; in the non-display region, the first sub-line layer covers the second sub-line layer, and another end of the side wire at least covers part of the surface of the first sub-line layer; or in the non-display region, the first sub-line layer at most covers part of the second sub-line layer, and one end of the side wire at least covers part of the surface of the second sub-line layer.

In some embodiments, the array substrate also includes a second insulating layer; the second insulating layer is disposed on the driver circuit layer and covers the at least one signal layer of the display region.

In a second aspect, one or more embodiments of the present application also provide a method for manufacturing an array substrate. The array substrate includes a display region and a non-display region. The non-display region is at least located on one side of the display region. The method includes the following steps.

A driver circuit layer is formed on a first surface of a substrate. The driver circuit layer includes at least one signal layer. The at least one signal layer extends from the display region to the non-display region.

A pad layer is formed on a side of the driver circuit layer facing away from the substrate. The pad layer is disposed in the display region and includes at least one pad. The at least one pad is electrically connected to the at least one signal layer.

In some embodiments, forming the pad layer on the side of the driver circuit layer away from the substrate includes the following: an initial pad layer is formed on the side of the driver circuit layer facing away from the substrate; the initial pad layer covers the display region and the non-display region; and the initial pad layer is patterned to form the pad layer.

### BRIEF DESCRIPTION OF DRAWINGS

FIG. 1 is a diagram illustrating the structure of an array substrate according to one or more embodiments of the present application.

FIG. 2 is another diagram illustrating the structure of an array substrate according to one or more embodiments of the present application.

FIG. 3 is another diagram illustrating the structure of an array substrate according to one or more embodiments of the present application.

FIG. 4 is another diagram illustrating the structure of an array substrate according to one or more embodiments of the present application.

FIG. 5 is another diagram illustrating the structure of an array substrate according to one or more embodiments of the present application.

FIG. 6 is another diagram illustrating the structure of an array substrate according to one or more embodiments of the present application.

FIG. 7 is another diagram illustrating the structure of an array substrate according to one or more embodiments of the present application.

FIG. 8 is another diagram illustrating the structure of an array substrate according to one or more embodiments of the present application.

FIG. 9 is a flowchart illustrating a method for manufacturing an array substrate according to one or more embodiments of the present application.

FIG. 10 is a diagram illustrating the front sectional structure of an array substrate corresponding to S10 according to one or more embodiments of the present application.

FIG. 11 is a diagram illustrating the side sectional structure of an array substrate corresponding to S10 according to one or more embodiments of the present application.

FIG. 12 is a diagram illustrating the front sectional structure of an array substrate corresponding to S11 according to one or more embodiments of the present application.

FIG. 13 is a diagram illustrating the side sectional structure of an array substrate corresponding to S11 according to one or more embodiments of the present application.

FIG. 14 is a diagram illustrating the front sectional structure of an array substrate forming a second insulating layer according to one or more embodiments of the present application.

FIG. 15 is a diagram illustrating the side sectional structure of an array substrate forming a second insulating layer according to one or more embodiments of the present application.

FIG. 16 is a diagram illustrating the front sectional structure of an array substrate forming an initial pad layer according to one or more embodiments of the present application.

FIG. 17 is a diagram illustrating the side sectional structure of an array substrate forming an initial pad layer according to one or more embodiments of the present application.

FIG. 18 is a diagram illustrating the front sectional structure of a non-display region of an array substrate with an initial pad layer patterned according to one or more embodiments of the present application.

FIG. 19 is a diagram illustrating the side sectional structure of a non-display region of an array substrate with an initial pad layer patterned according to one or more embodiments of the present application.

FIG. 20 is a diagram illustrating the structure of an array substrate corresponding to the development process when the test pad is removed after a pad is formed according to the related art.

FIG. 21 is a diagram illustrating the structure of an array substrate when the test pad is removed after a pad is formed according to the related art.

FIG. 22 is a diagram illustrating the structure of an array substrate after a protective layer is patterned according to one or more embodiments of the present application.

FIG. 23 is a diagram illustrating the structure of an array substrate after the pad layer in the non-display region is removed according to one or more embodiments of the present application.

FIG. 24 is a diagram illustrating the structure of an array substrate after a second insulating layer in the non-display region is removed according to one or more embodiments of the present application.

FIG. 25 is a diagram illustrating the structure of an array substrate after a protective layer of the display region is peeled off according to one or more embodiments of the present application.

FIG. 26 is a diagram illustrating the structure of a display panel according to one or more embodiments of the present application.

### DETAILED DESCRIPTION

Hereinafter the present application is further described in detail in conjunction with the drawings and embodiments. It is to be understood that the embodiments described herein are only intended to illustrate but not to limit the present application. Additionally, it is to be noted that, for ease of description, only part, not all, of structures related to the present application are illustrated in the drawings.

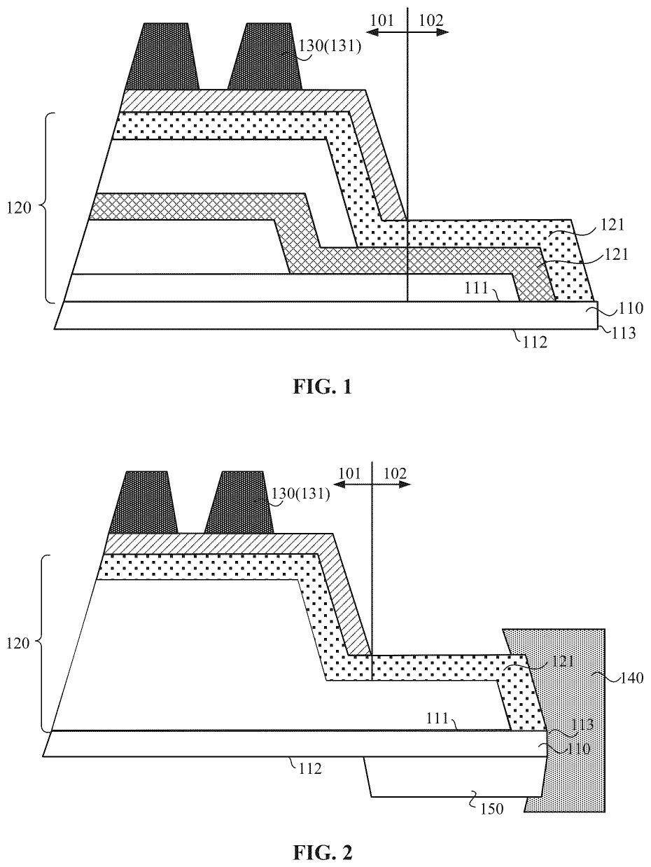

In the related art, micro-LED/mini-LED display panels include thick copper layers configured to form pads. The pads are connected to the electrodes of the micro-LEDs/mini-LEDs to provide drive signals for the micro-LEDs/mini-LEDs. In the process of manufacturing micro-LED/mini-LED display panels, the thick copper layers of non-display regions need to be reserved to avoid damage to other conductive layers when the thick copper layers are patterned. In this case, the signal lines of display regions are connected to side wires through the thick copper layers of the non-display regions. Since the thickness of the stacked structures formed by the thick copper layers in the non-display regions and the signal lines is relatively large, it is easy to have residue between stacked structures when the organic substances in the etching technique are removed after the thick copper layers are patterned. When the laser cutting technique is used to form side wires, the residual organic substances tend to cause short circuits and circuit defects, thus reducing the reliability of display panels. FIG. 1 is a diagram illustrating the structure of an array substrate according to one or more embodiments of the present application. As shown in FIG. 1, the array substrate includes a display region 101 and a non-display region 102; the non-display region 102 is at least located on one side of the display region 101; and the array substrate also includes a substrate 110, a driver circuit layer 120, and a pad layer 130.

The substrate 110 includes a first surface 111, a second surface 112 and a side surface 113. The first surface 111 and the second surface 112 are disposed opposite to each other. The side surface 113 is connected to the first surface 111 and the second surface 112.

The driver circuit layer 120 is disposed on the first surface 111 and includes at least one signal layer 121. The at least one signal layer 121 extends from the display region 101 to the non-display region 102.

The pad layer 130 is disposed in the display region 101 and includes at least one pad 131. The at least one pad 131 is electrically connected to the at least one signal layer 121.

Illustratively, the substrate 110 is used to support the driver circuit layer 120. Illustratively, the material of the substrate 110 may be glass or polyimide (PI). The driver circuit layer 120 may include an active layer, multiple conductive layers, and multiple insulating layers that are configured to form a transistor, a capacitor, and a connection line in a pixel driving circuit. The driver circuit layer 120 may include a signal layer 121. The at least one signal layer 121 includes at least one signal line. A signal line may provide a drive signal for the pixel driving circuit. The signal line in the at least one signal layer 121 extends from the display region 101 to the non-display region 102 and is connected to a driver chip to receive a drive signal provided by the driver chip. Illustratively, the at least one signal line in the at least one signal layer 121 may include a first power signal line, a second power signal line, and a data signal line. The array substrate may also include a side wire. The driver chip may be disposed on the back of the array substrate. The at least one signal line in the at least one signal layer 121 may be connected to the driver chip through the side wire to reduce the size of the side frame of the array substrate. One or more first power signal lines, one or more second power signal lines, and one or more data signal lines may be separately arranged as required. The pad layer 130 is disposed in the display region 101 and includes at least one pad 131. The pad 131 is electrically connected to the at least one signal layer 121 and may receive the drive signal provided by the at least one signal line in the at least one signal layer 121. In addition, the pad 131 may be connected to a light-emitting diode to provide a drive current for the light-emitting diode to cause the light-emitting diode to emit light. Moreover, the pad layer 130 is only disposed in the display region 101 to prevent the pad layer 130 from forming a stacked structure with the at least one signal layer 121 in the non-display region 102 so that the thickness of the stacked structure is reduced, thereby reducing the amount of residual organic substances near the stacked structure, lowering the probability of short circuits caused by the residual organic substances and improving the reliability of display panels. Illustratively, when the pad 131 is formed in the pad layer 130, the photolithography technique may be used to pattern the pad layer 130 to form the pad 131. In this case, the photoresist needs to be covered in a non-pad region of the pad layer 130 so that the photoresist remains near the stacked structure. The pad layer 130 is only disposed in the display region 101 so that the thickness of the stacked structure in the non-display region can be reduced. The smaller thickness of the stacked structure results in less photoresist remaining near the stacked structure. In a subsequent technique, the probability of short circuits caused by carbonization of the photoresist can be reduced, thereby improving the reliability of display panels.

According to the technical solution of the embodiments, the pad layer is disposed in the display region so that it is possible to prevent the pad layer from forming a stacked structure with the at least one signal layer in the non-display region so that the thickness of the stacked structure is reduced, thereby reducing the amount of residual organic substances near the stacked structure, lowering the probability of short circuits caused by residual organic substances and improving the reliability of display panels.

FIG. 2 is a diagram illustrating the structure of another array substrate according to one or more embodiments of the present application. As shown in FIG. 2, the array substrate also includes a side wire 140 and a line layer 150. The liner layer 150 is disposed on the second surface 112. The side wire 140 is disposed on a side surface 113 of the substrate 110, one end of the side wire 140 is connected to the at least one signal layer 121, and another end of the side wire 140 is connected to the line layer 150. In some embodiments, the array substrate may include one or more side wires 140.

Illustratively, the side wire 140 may be arranged corresponding to the at least one signal layer 121, one end of the side wire 140 is connected to a signal line of the at least one signal layer 121, and another end of the side wire 140 is connected to the line layer 150. Thus, the line layer 150 is electrically connected to the at least one signal layer 121 through the side wire 140. The line layer 150 is disposed on the second surface 112, may be connected to the driver chip, and is configured to provide a drive signal for the at least one signal layer 121. The side wire 140 and the line layer 150 are configured to be connected so that the driver chip may be set on the second surface 112. In this manner, it is beneficial to reduce the size of the frame of the array substrate. The side wire 140 may be formed using the laser cutting technique. After the pad 131 is formed on the pad layer 130, a side wire layer may be formed on the non-display region 102 and be lapped on a stacked structure formed on the signal layer 121; then the side wire layer is cut using the laser cutting technique to form the side wire 140. Since the thickness of the stacked structure is relatively small, when an organic substance is removed from the pad 131, residual organic substances near the stacked structure are less. Laser cutting of the side wire layer can reduce the carbonization of organic substances, thereby reducing the probability of short circuits caused by residual organic substances and improving the reliability of display panels.

With continued reference to FIG. 2, the at least one signal layer 121 in the non-display region 102 extends to an edge of the first surface 111, and one end of the side wire 140 is lapped on the surface of the at least one signal layer 121.

Illustratively, as shown in FIG. 2, when the at least one signal layer 121 in the non-display region 102 extends to an edge of the first surface 111, the at least one signal line of the at least one signal layer 121 extends to the edge of the first surface 111. In this case, the side wire 140 may be lapped with the at least one signal layer 121 on the edge of the first surface 111 to achieve electrical connection between the side wire 140 and the at least one signal layer 121.

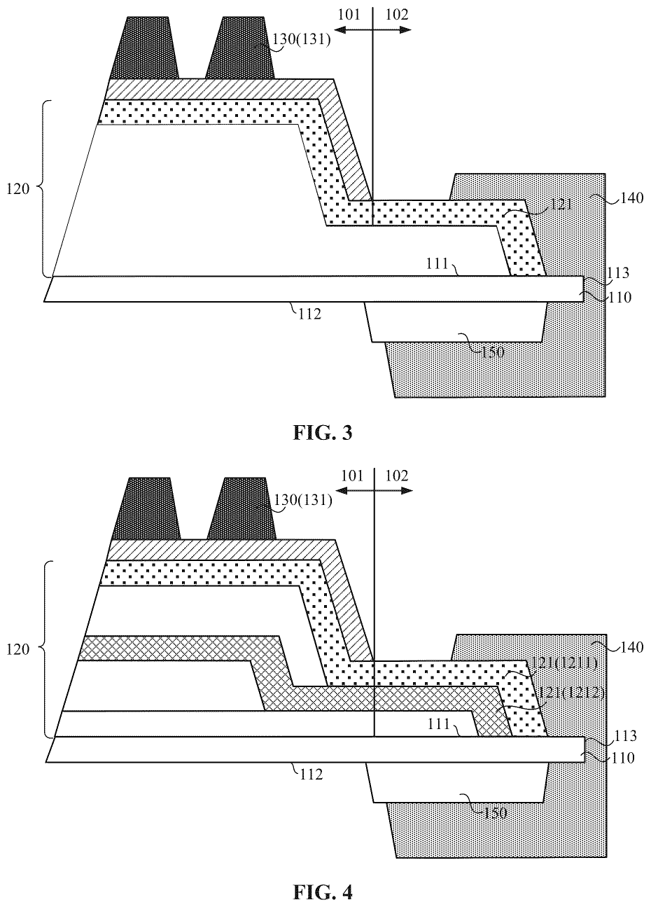

FIG. 3 is a diagram illustrating the structure of another array substrate according to one or more embodiments of the present application. As shown in FIG. 3, in other embodiments, a certain distance is reserved between the at least one signal layer 121 in the non-display region 102 and an edge of the first surface 111, and one end of the side wire 140 extends along the first surface 111 to be lapped on the surface of the at least one signal layer 121.

Illustratively, what is different from FIG. 2 is that in FIG. 3, when the at least one signal layer 121 extends along the first surface 111, a certain distance exists between the edge of the at least one signal layer 121 and the edge of the first surface 111, that is, a certain distance exists between one end of the signal line of the at least one signal layer 121 in the non-display region 102 and the edge of the first surface 111. In this case, the side wire 140 may extend along the first surface 111 so that the side wire 140 is lapped with the at least one signal layer 121 on the first surface 111 to achieve electrical connection between the side wire 140 and the at least one signal layer 121.

It should be noted that the distance between the at least one signal layer 121 in the non-display region 102 and the edge of the first surface 111 may be set as required, which is not limited herein.

FIG. 4 is a diagram illustrating the structure of another array substrate according to one or more embodiments of the present application. As shown in FIG. 4, the at least one signal layer 121 includes a first signal layer 1211 and a second signal layer 1212; in the non-display region 102, the first signal layer 1211 covers the second signal layer 1212; and one end of the side wire 140 at least covers part of the surface of the first signal layer 1211.

Illustratively, the at least one signal layer 121 may include multiple signal lines for transmitting different drive signals. Illustratively, a signal line may include a first power signal line, a second power signal line, and a data signal line. Different signal lines may be disposed in the first signal layer 1211 and the second signal layer 1212. When the number of signal lines is relatively large, the layout of the signal lines is simplified. Alternatively, different signal lines may be disposed at the same signal layer, while another signal layer is used to set jumpers of signal lines with different directions at overlapping positions to avoid short circuiting of signal lines with different directions. Illustratively, the first signal layer 1211 is configured to set signal lines with different directions, and the second signal layer 1212 is configured to set jumpers of signal lines with different directions at overlapping positions. In the non-display region 102, when the first signal layer 1211 covers the second signal layer 1212, the surface of the at least one signal layer 121 away from the substrate 110 is the surface of the first signal layer 1211. In this case, one end of the side wire 140 is configured to at least cover part of the surface of the first signal layer 1211 to achieve the lap between the side wire 140 and the at least one signal layer 121 and ensure the connection reliability between the side wire 140 and the at least one signal layer 121. Illustratively, as shown in FIG. 4, one end of the side wire 140 covers the surface of the first signal layer 1211, thereby further ensuring the connection reliability between the side wire 140 and the at least one signal layer 121.

It should be noted that FIG. 4 illustratively shows a case where the first signal layer 1211 covers the second signal layer 1212 when a certain distance is reserved between the at least one signal layer 121 in the non-display region 102 and the edge of the first surface 111. In other embodiments, when the at least one signal layer 121 in the non-display region 102 extends to the edge of the first surface 111, the first signal layer 1211 covers the second signal layer 1212, which is not limited herein.

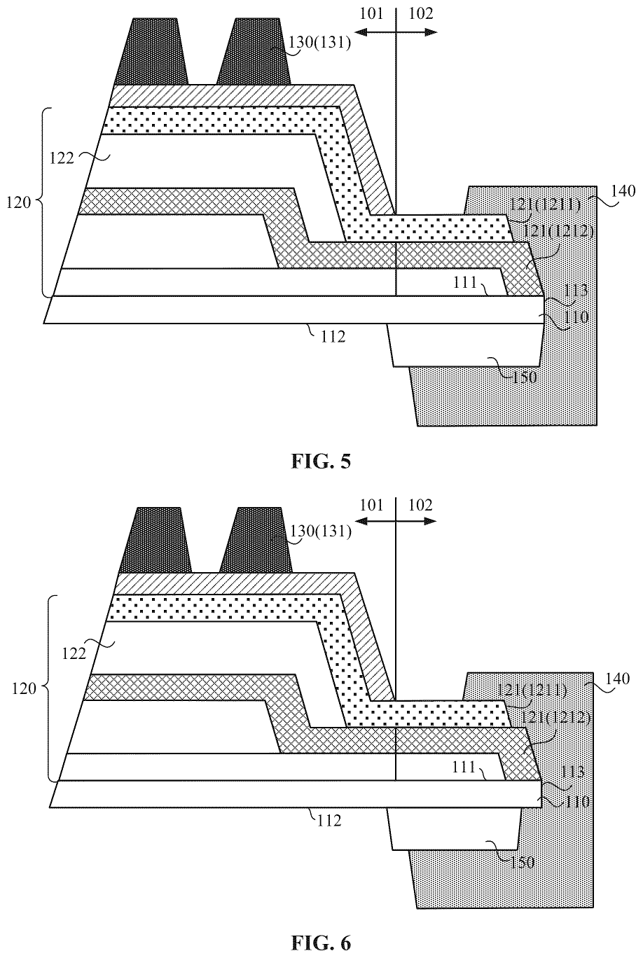

FIG. 5 is a diagram illustrating the structure of another array substrate according to one or more embodiments of the present application. As shown in FIG. 5, in other embodiments, the at least one signal layer 121 includes a first signal layer 1211 and a second signal layer 1212; in the non-display region 102, the first signal layer 1211 at most covers part of the second signal layer 1212; and one end of the side wire 140 covers at least one of the following: part of the surface of the first signal layer 1211 and part of the surface of the second signal layer 1212.

Illustratively, in the non-display region 102, when the first signal layer 1211 at most covers part of the second signal layer 1212, the surface of the at least one signal layer 121 facing away from the substrate 110 includes the surface of the first signal layer 1211 and the surface of the second signal layer 1212 that is not covered by the first signal layer 1211. In this case, the side wire 140 may cover at least one of the following: part of the surface of the first signal layer 1211 and part of the surface of the second signal layer 1212 to achieve electrical connection between the side wire 140 and the at least one signal layer 121. Illustratively, as shown in FIG. 5, the side wire 140 may cover the surface of the first signal layer 1211 and the surface of the second signal layer 1212 that is not covered by the first signal layer 1211, thereby ensuring the connection reliability between the side wire 140 and the at least one signal layer 121.

It should be noted that FIG. 5 illustratively shows a case where the at least one signal layer 121 in the non-display region 102 extends to an edge of the first surface 111. In other embodiments, when a certain distance is reserved between the at least one signal layer 121 in the non-display region 102 and the edge of the first surface 111, the first signal layer 1211 at most covers part of the second signal layer 1212, which is not limited herein. In addition, FIG. 5 illustratively shows the technical solution where the first signal layer 1211 covers part of the second signal layer 1212. In other embodiments, in the non-display region 102, the vertical projection of the first signal layer 1211 on the substrate 110 may not overlap but be in contact with the vertical projection of the second signal layer 1212 on the substrate 110 to achieve electrical connection between the first signal layer 1211 and the second signal layer 1212.

In addition, FIG. 5 illustratively shows the technical solution where the side wire 140 covers the surfaces of the first signal layer 1211 and the second signal layer 1212. In other embodiments, a technical solution may also be provided where the side wire 140 at least covers part of the surface of the first signal layer 1211 or part of the surface of the second signal layer 1212 to achieve the lap between the side wire 140 and the at least one signal layer 121. No limitation is imposed herein.

With continued reference to FIG. 5, the driver circuit layer also includes a first insulating layer 122, and the first insulating layer 122 is disposed in the display region 101 and disposed between the first signal layer 1211 and the second signal layer 1212.

Illustratively, in the display region 101, a first insulating layer 122 is disposed between the first signal layer 1211 and the second signal layer 1212 to achieve the insulation between the first signal layer 1211 and the second signal layer 1212. In addition, a via may be disposed on the first insulating layer 122 to achieve electrical connection between the first signal layer 1211 and the second signal layer 1212. The first insulating layer 122 may be an inorganic insulating layer and is only disposed in the display region 101. Thus, the thickness of the inorganic layer in the non-display region 102 can be reduced, the first insulating layer 122 is prevented from remaining in the non-display region 102, and reducing the risk of short-circuit of the signal lines in the non-display region 102 and short-circuit of the side wire 140.

With continued reference to FIG. 5, the line layer 150 in the non-display region 102 extends to an edge of the second surface 112, and another end of the side wire 140 is lapped on the surface of the line layer 150.

Illustratively, the line layer 150 includes lines arranged corresponding to the side wire 140, that is, the lines in the line layer 150 are arranged corresponding to the signal lines in the at least one signal layer 121 and are lapped with the side wire 140 so that the lines in the line layer 150 are connected to the at least one signal layer 121 through the side wire 140. Thus, the lines in the line layer 150 may separately provide drive signals for the signal lines in the at least one signal layer 121 through the side wire 140. In addition, another end of the line layer 150 may be connected to the driver chip for acquiring the drive signal. As shown in FIG. 5, when the line layer 150 in the non-display region 102 extends to the edge of the second surface 112, the side wire 140 may be lapped with the line layer 150 on the edge of the second surface 112 to achieve electrical connection between the another end of the side wire 140 and the line layer 150.

FIG. 6 is a diagram illustrating the structure of another array substrate according to one or more embodiments of the present application. As shown in FIG. 6, in other embodiments, a certain distance is reserved between the line layer 150 in the non-display region 102 and an edge of the second surface 112, and another end of the side wire 140 extends along the second surface 112 to be lapped on the surface of the line layer 150.

Illustratively, what is different from FIG. 5 is that in FIG. 6, when the line layer 150 extends along the second surface 112, a certain distance exists between the edge of the line layer 150 and the edge of the second surface 112, that is, a certain distance exists between one end of the line in the line layer 150 in the non-display region 102 and the edge of the second surface 112. In this case, the side wire 140 may extend along the second surface 112 so that the side wire 140 is lapped with the line layer 150 on the second surface 112 to achieve electrical connection between the side wire 140 and the line layer 150.

FIG. 7 is a diagram illustrating the structure of another array substrate according to one or more embodiments of the present application. As shown in FIG. 7, the line layer 150 at least includes a first sub-line layer 151 and a second sub-line layer 152; in the non-display region 102, the first sub-line layer 151 covers the second sub-line layer 152, and another end of the side wire 140 covers at least part of the surface of the first sub-line layer 151.

Illustratively, the line layer 150 includes multiple lines that are arranged corresponding to the signal lines in the at least one signal layer 121, respectively through the side wire 140. The multiple lines in the line layer 150 are used to provide different drive signals for the signal lines. Illustratively, when the signal lines in the at least one signal layer 121 include a first power signal line, a second power signal line, and a data signal line, the line layer 150 includes a first line, a second line, and a third line that are connected to the first power signal line, the second power signal line, and the data signal line, respectively and provide drive signals for the first power signal line, the second power signal line, and the data signal line respectively. The line layer 150 may include a first sub-line layer 151 and a second sub-line layer 152. Multiple lines may be disposed in the first sub-line layer 151 and the second sub-line layer 152. When the number of lines in the line layer 150 is relatively large, the layout of the lines is simplified. Alternatively, when different lines have different directions, different lines may be disposed at the same sub-line layer, and the other sub-line layer may set jumpers of lines with different directions at overlapping positions to avoid lines with different directions being short-circuited. Illustratively, the first sub-line layer 151 is configured to set lines with different directions, and the second sub-line layer 152 is configured to set jumpers of lines with different directions at overlapping positions. In the non-display region 102, when the first sub-line layer 151 covers the second sub-line layer 152, the surface of the line layer 150 facing away from the substrate 110 is the surface of the first sub-line layer 151. In this case, another end of the side wire 140 is configured to cover at least part of the surface of the first sub-line layer 151 to achieve the lap between the side wire 140 and the line layer 150 and ensure the connection reliability between the side wire 140 and the line layer 150. Illustratively, as shown in FIG. 7, another end of the side wire 140 covers the surface of the first sub-line layer 151, thereby further ensuring the connection reliability between the side wire 140 and the line layer 150.

It should be noted that FIG. 7 illustratively shows a case where the first sub-line layer 151 covers the second sub-line layer 152 when the line layer 150 in the non-display region 102 extends to the edge of the second surface 112. In other embodiments, when a certain distance is reserved between the line layer 150 in the non-display region 102 and the edge of the second surface 112, the first sub-line layer 151 covers the second sub-line layer 152, which is not limited herein.

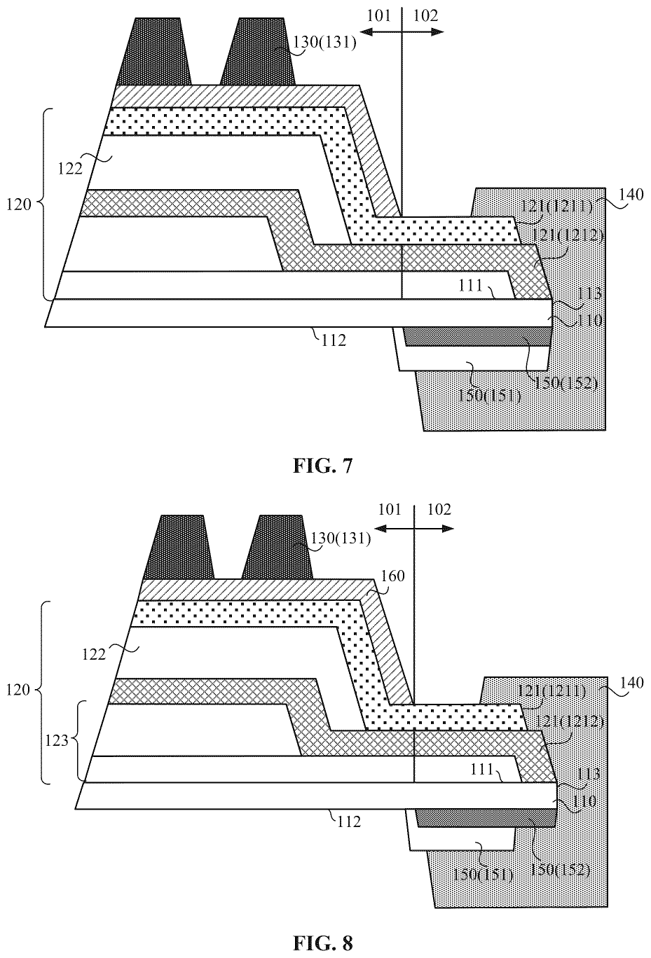

FIG. 8 is a diagram illustrating the structure of another array substrate according to one or more embodiments of the present application. As shown in FIG. 8, the line layer 150 at least includes a first sub-line layer 151 and a second sub-line layer 152; in the non-display region 102, the first sub-line layer 151 at most covers part of the second sub-line layer 152, and one end of the side wire 140 at least covers part of the surface of the second sub-line layer 152.

Illustratively, in the non-display region 102, when the first sub-line layer 151 at most covers part of the second sub-line layer 152, the surface of the line layer 150 facing away from the substrate 110 includes the surface of the first sub-line layer 151 and the surface of the second sub-line layer 152 that is not covered by the first sub-line layer 151. In this case, the side wire 140 may at least cover part of the surface of the second sub-line layer 152 to achieve electrical connection between the side wire 140 and the line layer 150. Illustratively, as shown in FIG. 8, the side wire 140 may cover the surface of the first sub-line layer 151 and the surface of the second sub-line layer 152 that is not covered by the first sub-line layer 151, thereby ensuring the connection reliability between the side wire 140 and the line layer 150.

It should be noted that FIG. 8 illustratively shows a technical solution where the first sub-line layer 151 covers part of the second sub-line layer 152. In other embodiments, in the non-display region 102, the vertical projection of the first sub-line layer 151 on the substrate 110 may not overlap but be in contact with the vertical projection of the second sub-line layer 152 on the substrate 110 to achieve electrical connection between the first sub-line layer 151 and the second sub-line layer 152.

In addition, FIG. 8 illustratively shows a technical solution where the side wire 140 covers the surfaces of the first sub-line layer 151 and the second sub-line layer 152. In other embodiments, a technical solution may also be provided where the side wire 140 at least covers part of the surface of the second sub-line layer 152 to achieve the lap between the side wire 140 and the line layer 150. No limitation is imposed herein.

With continued reference to FIG. 8, the array substrate also includes a second insulating layer 160; the second insulating layer 160 is disposed on the driver circuit layer 120 and covers the at least one signal layer 121 in the display region 101.

Illustratively, in the display region 101, the second insulating layer 160 is disposed between the at least one signal layer 121 and the pad layer 130 and is configured to achieve the insulation between the at least one signal layer 121 and the pad layer 130. In addition, a via may be disposed in the second insulating layer 160 to achieve electrical connection between the at least one signal layer 121 and the pad layer 130. When the second insulating layer 160 is formed, the entire second insulating layer 160 may be first formed on the display region 101 and the non-display region 102, and then the pad layer 130 is formed on the second insulating layer 160 and is patterned so that the pad layer 130 is only disposed in the display region 101. Then, the entire second insulating layer 160 is patterned so that the second insulating layer 160 is only disposed in the display region 101 and covers the at least one signal layer 121. The pad layer 130 is then patterned to form a pad 131. The second insulating layer 160 in the non-display region 102 may be used as a protective layer to avoid the loss of the at least one signal layer 121 when the pad layer 130 is patterned at the first time.

With continued reference to FIG. 8, the driver circuit layer 120 also includes a pixel circuit layer 123 disposed on the substrate 110; the at least one signal layer 121 is disposed on a side of the pixel circuit layer 123 facing away from the substrate 110; the pixel circuit layer 123 is configured to form a pixel circuit, the at least one signal layer 121 is configured to form a signal line, and the at least one signal layer 121 is connected to the pixel circuit to provide a drive signal for the pixel circuit.

Illustratively, the pixel circuit layer 123 has a multi-layer structure and is configured to form a transistor, a capacitor, and a connection line in the pixel circuit. Illustratively, the pixel circuit layer 123 may include an active layer, a first metal layer, a gate insulating layer, a second metal layer, an interlayer insulating layer, and a third metal layer. The active layer is configured to form a channel region, a source region, and a drain region in a transistor. The first metal layer is configured to form a gate of the transistor, a first electrode of a capacitor, and a connection line. The second metal layer is configured to form a second electrode of the capacitor. The third metal layer is configured to form a source, a drain, and a connection line. The at least one signal layer 121 may include multiple conductive layers for forming signal lines. Illustratively, as shown in FIG. 8, the at least one signal layer 121 may include a fourth metal layer and a fifth metal layer. When the at least one signal layer 121 includes a data signal line, a first power signal line, and a second power signal line, the fourth metal layer may be configured to form the data signal line, and the fifth metal layer may be configured to form the first power signal line and the second power signal line. Alternatively, the fourth metal layer may be configured to form a jumper, and the fifth metal layer may be configured to form the data signal line, the first power signal line, and the second power signal line. The data signal line has a different extension direction from the first power signal line. At the overlapping position between the data signal line and the first power signal line, a jumper may be used to span the data signal line or the first power signal line to prevent the data signal line and the first power signal line from overlapping and being short-circuited.

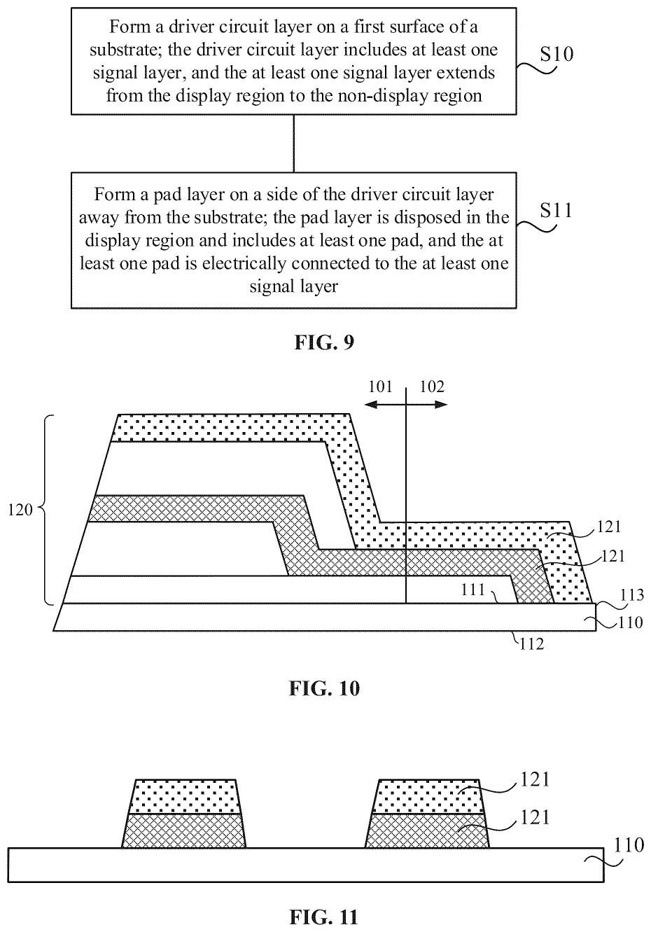

Embodiments of the present application also provide a method for manufacturing an array substrate, which can be used to manufacture an array substrate provided by any embodiment of the present application. The array substrate includes a display region 101 and a non-display region 102. The non-display region 102 is at least located on one side of the display region 101. FIG. 9 is a flowchart illustrating a method for manufacturing an array substrate according to one or more embodiments of the present application. As shown in FIG. 9, the method includes the steps described below.

In S10, a driver circuit layer is formed on a first surface of a substrate; the driver circuit layer includes at least one signal layer, and the at least one signal layer extends from the display region to the non-display region.

FIG. 10 is a diagram illustrating the front sectional structure of an array substrate corresponding to S10 according to one or more embodiments of the present application. FIG. 11 is a diagram illustrating the side sectional structure of an array substrate corresponding to S10 according to one or more embodiments of the present application. As shown in FIG. 10 and FIG. 11, the driver circuit layer 120 is disposed on the first surface 111 of the substrate 110, at least one signal layer 121 is disposed on the driver circuit layer 120, and the at least one signal layer 121 extends from the display region 101 to the non-display region 102. For example, as shown in FIG. 10, the at least one signal layer 121 may include the first signal layer 1211 and the second signal layer 1212 in the preceding embodiments. The at least one signal layer 121 has multiple signal lines. FIG. 11 illustratively shows that the at least one signal layer 121 has two signal lines.

In S11, a pad layer is formed on a side of the driver circuit layer facing away from the substrate; the pad layer is disposed in the display region and includes at least one pad, and the at least one pad is electrically connected to the at least one signal layer.

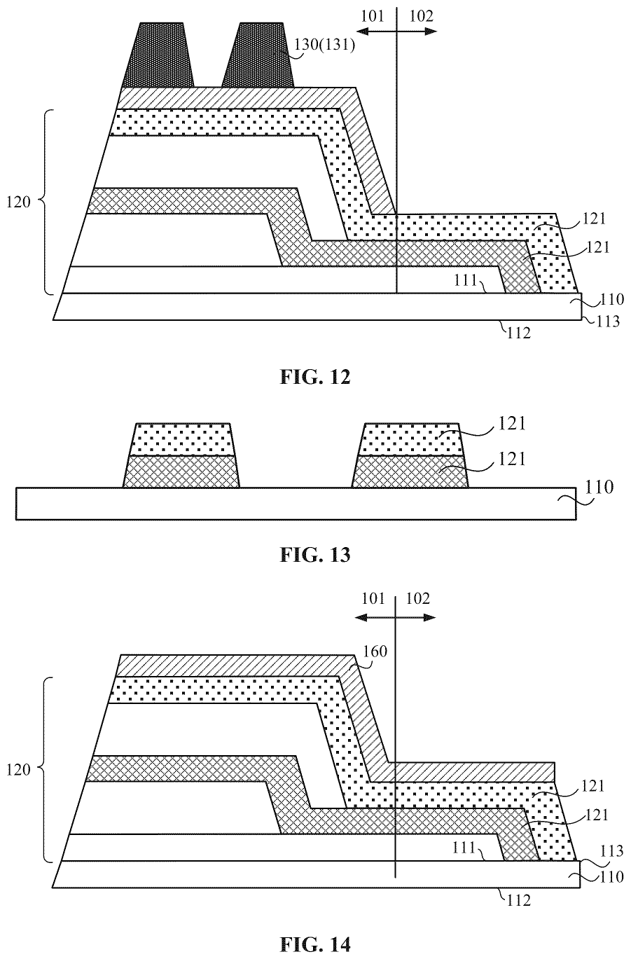

Illustratively, FIG. 12 is a diagram illustrating the front sectional structure of an array substrate corresponding to S11 according to one or more embodiments of the present application; FIG. 13 is a diagram illustrating the side sectional structure of an array substrate corresponding to S11 according to one or more embodiments of the present application. As shown in FIGS. 12 and 13, when the pad layer 130 is formed, the pad layer 130 is configured to be only disposed in the display region 101 to prevent the pad layer 130 from forming a stacked structure with the at least one signal layer 121 in the non-display region 102 so that the thickness of the stacked structure is reduced, thereby reducing the amount of residual organic substances near the stacked structure, lowering the probability of short circuits caused by residual organic substances, and improving the reliability of display panels.

According to the technical solution of the embodiments, the pad layer is formed in the display region so that only the at least one signal layer forms a stacked structure in the non-display region. In this manner, the thickness of the stacked structure is reduced, thereby reducing the amount of residual organic substances near the stacked structure, lowering the probability of short circuits caused by residual organic substances, and improving the reliability of display panels.

Based on the preceding technical solution, forming the pad layer on the side of the driver circuit layer facing away from the substrate includes the following.

An initial pad layer is formed on the side of the driver circuit layer facing away from the substrate; the initial pad layer covers the display region and the non-display region.

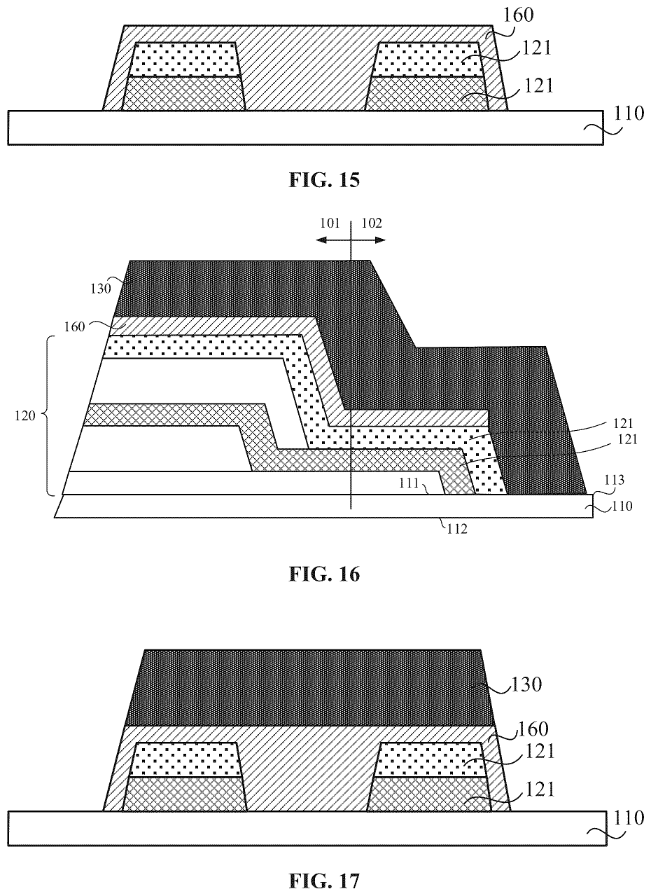

Illustratively, before the initial pad layer is formed, a second insulating layer may also be formed on the driver circuit layer, and the second insulating layer covers the at least one signal layer. Illustratively, FIG. 14 is a diagram illustrating the front sectional structure of an array substrate forming a second insulating layer according to one or more embodiments of the present application; FIG. 15 is a diagram illustrating the side sectional structure of an array substrate forming a second insulating layer according to one or more embodiments of the present application. As shown in FIG. 14 and FIG. 15, the second insulating layer 160 is disposed on the driver circuit layer 120 and covers the at least one signal layer 121 so that the second insulating layer can protect the at least one signal layer 121 of the display region 101 and the non-display region 102. After the second insulating layer 160 is formed, an initial pad layer is formed on the second insulating layer 160, and the initial pad layer covers the display region 101 and the non-display region 102. Illustratively, FIG. 16 is a diagram illustrating the front sectional structure of an array substrate forming an initial pad layer according to one or more embodiments of the present application; FIG. 17 is a diagram illustrating the side sectional structure of an array substrate forming an initial pad layer according to one or more embodiments of the present application. As shown in FIGS. 16 and 17, the initial pad layer covers the display region 101 and the non-display region 102. Illustratively, the initial pad layer may be a thick copper layer and is configured to form the pad layer 130.

The initial pad layer is patterned to form the pad layer.

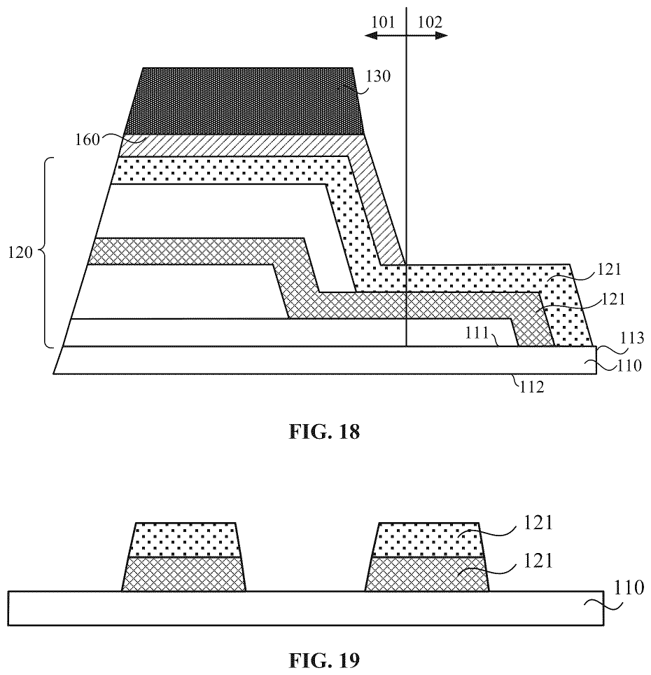

Illustratively, FIG. 18 is a diagram illustrating the front sectional structure of a non-display region of an array substrate with an initial pad layer patterned according to one or more embodiments of the present application; FIG. 19 is a diagram illustrating the side sectional structure of a non-display region of an array substrate with an initial pad layer patterned according to one or more embodiments of the present application. As shown in FIG. 18 and FIG. 19, the initial pad layer in the non-display region 102 may be first removed when the initial pad layer is patterned. Then, the second insulating layer 160 in the non-display region 102 is removed so that only the at least one signal layer 121 in the non-display region 102 forms a stacked structure. In this manner, the thickness of the stacked structure is reduced, thereby reducing the amount of residual organic substances near the stacked structure, lowering the probability of short circuits caused by residual organic substances, and improving the reliability of display panels. The initial pad layer in the display region 101 is then patterned again to form the pad 131. When the initial pad layer in the display region 101 is patterned again to form the pad 131, the non-pad region of the display region 101 and the non-display region 102 may be covered with organic substances to avoid the influence on the at least one signal layer 121 when the initial pad layer is patterned, thus ensuring the reliability of the at least one signal layer 121. In addition, the patterned technique can be avoided, and costs of manufacturing the array substrate can be reduced.

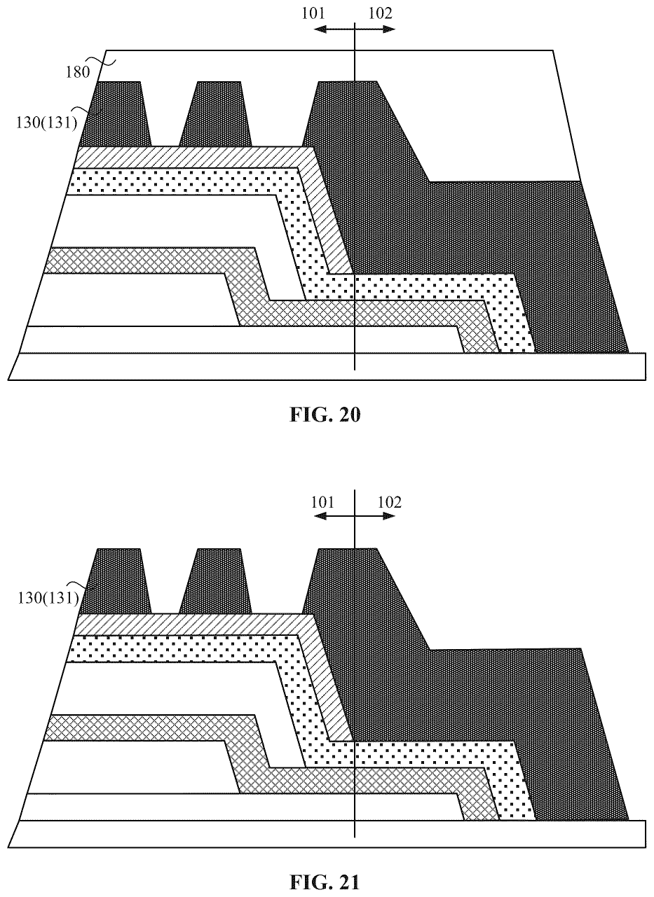

In addition, FIG. 20 is a diagram illustrating the structure of an array substrate corresponding to the development process when the test pad is removed after a pad is formed according to the related art; FIG. 21 is a diagram illustrating the structure of an array substrate when the test pad is removed after a pad is formed according to the related art. As shown in FIGS. 20 and 21, when the pad layer 130 is patterned to form the pad 131 in the display region 101, a test pad (not shown in FIGS. 20 and 21) may be simultaneously formed in the non-display region 102 for connecting test signals to the array substrate to test the reliability of the array substrate. After the test, the pad layer 130 is patterned again to remove the test pad of the non-display region 102. The process may be shown in FIG. 20 and FIG. 21. First, the test pad is exposed using the development technique, then the test pad is etched out, and finally, the organic adhesive 180 is peeled off. The related art includes the patterning technique of removing the test pad. This embodiment uses the patterning technique of removing the test pad in the related art to pattern the pad layer in the display region to form the pad. Thus, additional patterning techniques can be avoided, and the cost of manufacturing the array substrate is saved.

Based on the preceding technical solutions, removing the initial pad layer in the non-display region may include the steps below.

A protective layer is formed on the pad layer.

The protective layer may be an organic adhesive. After the organic adhesive being patterned, the organic adhesive may be used to pattern a mask version of the pad layer later.

The protective layer is patterned to remove the protective layer in the non-display region.

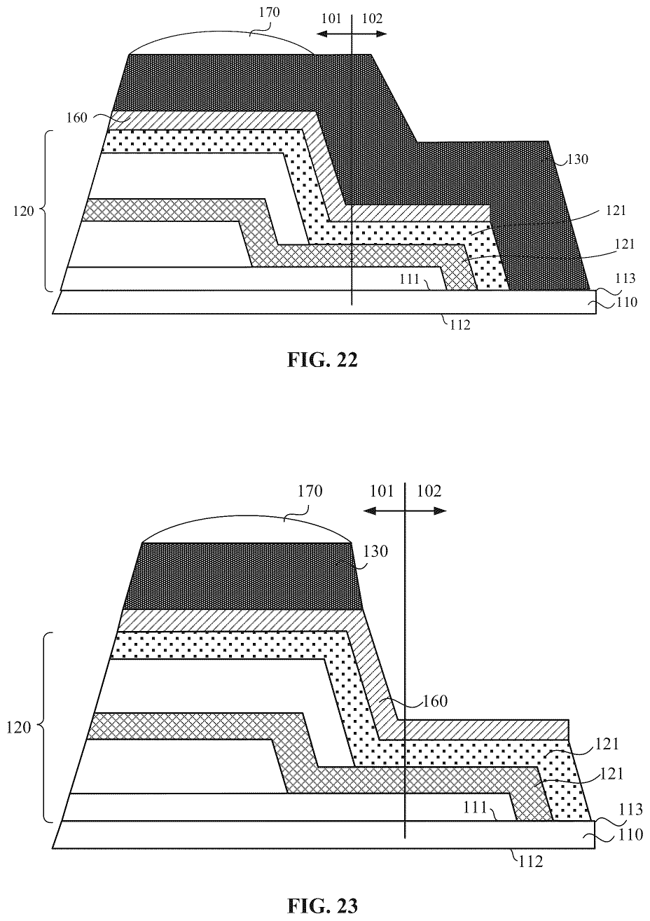

The developing technique may be used to pattern the protective layer. Illustratively, FIG. 22 is a diagram illustrating the structure of an array substrate after a protective layer is patterned according to one or more embodiments of the present application. As shown in FIG. 22, after the protective layer 170 is patterned, the protective layer 170 in the display region 101 is configured to protect the pad layer 130, and the pad layer 130 in the non-display region 102 is exposed.

The pad layer is etched to remove the pad layer in the non-display region.

FIG. 23 is a diagram illustrating the structure of an array substrate after the pad layer in the non-display region is removed according to one or more embodiments of the present application. As shown in FIG. 23, after the pad layer 130 is etched, only the second insulating layer 160 and the at least one signal layer 121 exist in the non-display region 102. In this case, a protective layer 170 is also disposed on the pad layer 130 in the display region 101 to prevent subsequent etching of the second insulating layer 160 from affecting the lower layer structure in the display region 101.

Based on the preceding technical solutions, removing the second insulating layer in the non-display region may include the steps below.

The second insulating layer is etched to remove the second insulating layer in the non-display region.

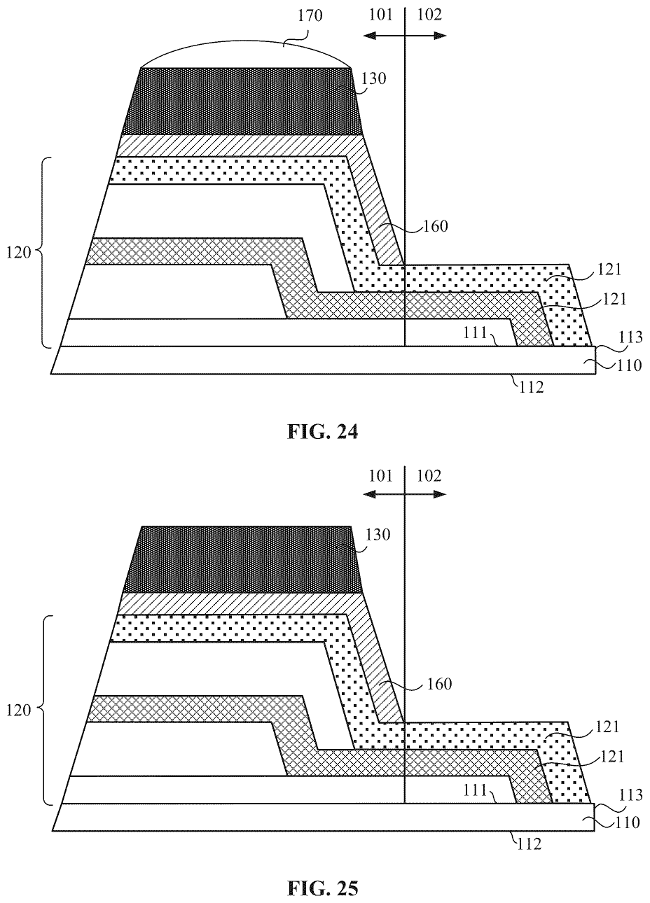

FIG. 24 is a diagram illustrating the structure of an array substrate after a second insulating layer in the non-display region is removed according to one or more embodiments of the present application. As shown in FIG. 24, after the pad layer 130 is etched, the protective layer 170 may protect the pad layer 130 in the display region 101. When the second insulating layer is etched, etching may be directly performed and no additional protective layer is needed to protect the layer of the display region 101, thus simplifying the process flow.

Preferably, the dry etching technique is used when an insulating layer is etched.

The protective layer in the display region is peeled off.

FIG. 25 is a diagram illustrating the structure of an array substrate after a protective layer in the display region is peeled off according to one or more embodiments of the present application. As shown in FIG. 25, after the second insulating layer 160 is etched, the protective layer in the display region 101 is peeled off for subsequent patterning of the pad layer 130 in the display region 101.

Based on the preceding technical solutions, the pad layer also includes at least one test pad disposed in the non-display region.

Illustratively, the pad layer may synchronously form at least one test pad in the non-display region for connecting test signals to the array substrate to test the reliability of the array substrate. After the test, the pad layer is patterned again to remove the at least one test pad in the non-display region. The process may be shown in FIG. 20 and FIG. 21. First, the test pad is exposed using the development technique, then the test pad is etched out, and finally, the organic adhesive is peeled off. The related art includes the patterning technique of removing the test pad.

Based on the preceding technical solutions, this embodiment, when patterning the pad layer of the display region, also includes the steps below.

The at least one test pad in the non-display region is removed.

After the pad layer is patterned to remove the pad layer in the non-display region, the patterning technique of removing the test pad in the related art is used to pattern the pad layer in the display region to form the pad, and at the same time, the test pad in the non-display region is removed. Thus, additional patterning techniques can be avoided, and the cost of manufacturing the array substrate is saved.

Based on the preceding technical solutions, a line layer may also be formed on the second surface of the substrate after the pad layer is formed on a side of the driver circuit layer facing away from the substrate. The formation technique may be a conventional technique of related art. Forming a side wire on a side of the substrate may adopt the laser cutting technique. The line layer may be electrically connected to the at least one signal layer through the side wire and is connected to the driver chip to provide a drive signal for the at least one signal layer.

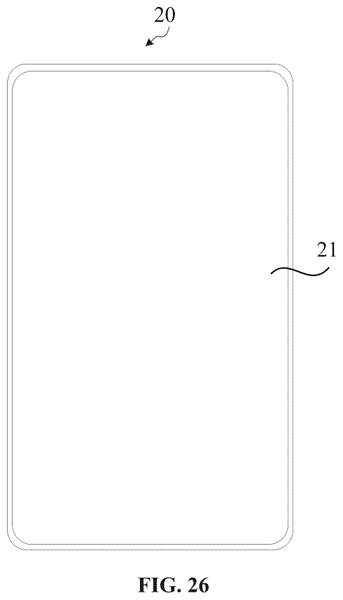

Embodiments of the present application also provide a display panel. FIG. 26 is a diagram illustrating the structure of a display panel according to one or more embodiments of the present application. As shown in FIG. 26, the display panel 20 includes an array substrate 21 provided by any embodiment of the present application.

Illustratively, the array substrate 21 is an array substrate provided by any embodiment of the present application. When the display panel 20 includes the array substrate provided by any embodiment of the present application, the display panel 20 has the same beneficial effect as the array substrate provided by any embodiment of the present application. The details are not repeated herein. The display panel 20 may be any product or component having a display function, such as a mobile phone, a tablet computer, a television, a display, a notebook computer, or a digital photo frame.

It is to be noted that the above are only preferred embodiments of the present application and the technical principles used therein. It is to be understood by those skilled in the art that the present application is not limited to the embodiments described herein. For those skilled in the art, various apparent modifications, adaptations, and substitutions may be made without departing from the scope of the present application. Therefore, while the present application is described in detail via the preceding embodiments, the present application is not limited to the preceding embodiments and may include more equivalent embodiments without departing from the concept of the present application. The scope of the present application is determined by the scope of the appended claims.

What is claimed is:

1. An array substrate, comprising a display region and a non-display region, wherein the non-display region is at least located on one side of the display region; and the array substrate further comprises:
a substrate, comprising a first surface and a second surface that are disposed opposite to each other and a side surface connected to the first surface and the second surface;
a driver circuit layer, disposed on the first surface and comprising at least one signal layer, wherein the at least one signal layer extends from the display region to the non-display region; and
a pad layer, disposed in the display region and comprising at least one pad, wherein the at least one pad is electrically connected to the at least one signal layer.

2. The array substrate of claim 1, further comprising a side wire and a line layer, wherein
the line layer is disposed on the second surface; and
the side wire is disposed on one side of the substrate, one end of the side wire is connected to the at least one signal layer, and another end of the side wire is connected to the line layer.

3. The array substrate of claim 2, wherein the at least one signal layer in the non-display region extends to an edge of the first surface, and the one end of the side wire is lapped on a surface of the at least one signal layer.

4. The array substrate of claim 2, wherein a certain distance is reserved between the at least one signal layer in the non-display region and an edge of the first surface, and the one end of the side wire extends along the first surface to be lapped on a surface of the at least one signal layer.

5. The array substrate of claim 2, wherein the at least one signal layer comprises a first signal layer and a second signal layer;
wherein in the non-display region, the first signal layer covers the second signal layer; and the one end of the side wire at least covers part of a surface of the first signal layer.

6. The array substrate of claim 2, wherein the at least one signal layer comprises a first signal layer and a second signal layer; and
in the non-display region, the first signal layer at most covers part of the second signal layer; and the one end of the side wire covers at least one of the following: part of a surface of the first signal layer and part of a surface of the second signal layer.

7. The array substrate of claim 5, wherein the driver circuit layer further comprises a first insulating layer, and the first insulating layer is disposed in the display region and disposed between the first signal layer and the second signal layer.

8. The array substrate of claim 6, wherein the driver circuit layer further comprises a first insulating layer, and the first insulating layer is disposed in the display region and disposed between the first signal layer and the second signal layer.

9. The array substrate of claim 2, wherein the line layer in the non-display region extends to an edge of the second surface, and the another end of the side wire is lapped on a surface of the line layer.

10. The array substrate of claim 2, wherein a certain distance is reserved between the line layer in the non-display region and an edge of the second surface, and the another end of the side wire extends along the second surface to be lapped on a surface of the line layer.

11. The array substrate of claim 2, wherein the line layer at least comprises a first sub-line layer and a second sub-line layer; and
in the non-display region, the first sub-line layer covers the second sub-line layer, and the another end of the side wire at least covers part of a surface of the first sub-line layer.

12. The array substrate of claim 2, wherein the line layer at least comprises a first sub-line layer and a second sub-line layer; and
in the non-display region, the first sub-line layer at most covers part of the second sub-line layer, and the one end of the side wire at least covers part of a surface of the second sub-line layer.

13. The array substrate of claim 1, further comprising a second insulating layer, wherein the second insulating layer is disposed on the driver circuit layer and covers the at least one signal layer in the display region.

14. A method for manufacturing an array substrate, wherein the array substrate comprises a display region and a non-display region, the non-display region is at least located on one side of the display region, and the method comprises:
forming a driver circuit layer on a first surface of a substrate, wherein the driver circuit layer comprises at least one signal layer, and the at least one signal layer extends from the display region to the non-display region; and
forming a pad layer on a side of the driver circuit layer facing away from the substrate; wherein the pad layer is disposed in the display region and comprises at least one pad, and the at least one pad is electrically connected to the at least one signal layer.

15. The method for manufacturing the array substrate of claim 14, wherein forming the pad layer on the side of the driver circuit layer away from the substrate comprises:
forming an initial pad layer on the side of the driver circuit layer away from the substrate; wherein the initial pad layer covers the display region and the non-display region; and
patterning the initial pad layer to form the pad layer.

16. The method for manufacturing the array substrate of claim 15, wherein before forming the initial pad layer, the method further comprising: forming a second insulating layer on the driver circuit layer, and the second insulating layer covers the at least one signal layer;
after forming the second insulating layer, forming the initial pad layer on the second insulating layer, and the initial pad layer covers the display region and the non-display region.

17. The method for manufacturing the array substrate of claim 16, wherein the patterning the initial pad layer to form the pad layer, comprising:
removing the initial pad layer in the non-display region;
removing the second insulating layer in the non-display region; and
patterning initial pad layer in the display region again to form the at least one pad.

18. The method for manufacturing the array substrate of claim 17, wherein removing the initial pad layer in the non-display region, comprising:
forming a protective layer on the pad layer;
patterning the protective layer to remove the protective layer in the non-display region; and
etching the pad layer to remove the pad layer in the non-display region.

19. The method for manufacturing the array substrate of claim 18, wherein removing the second insulating layer in the non-display region, comprising:
etching the second insulating layer to remove the second insulating layer in the non-display region.

20. The method for manufacturing the array substrate of claim 19, wherein the method further comprising:
peeling off the protective layer in the display region.
